(19) United States
(12) Patent Application Publication
(10) Pub. No.: US 2017/0018372 A1
(43) Pub. Date: Jan. 19, 2017

(54) SOLAR CELL INCLUDING COMPOUND HAVING PEROVSKITE STRUCTURE

(71) Applicant: Panasonic Corporation, Osaka (JP)

(72) Inventor: SHINYA FUJIMURA, Osaka (JP)

(21) Appl. No.: 15/196,127

(22) Filed: Jun. 29, 2016

(30) Foreign Application Priority Data
Jul. 14, 2015 (JP) 2015-140173

(51) Int. Cl. H01G 9/20; H01L 51/42

(52) U.S. Cl. CPC H01G 9/2059; H01L 51/4226; H01G 9/2031; H01L 51/0077

(57) ABSTRACT

A solar cell includes a first electrode; a light-absorbing layer, on the first electrode, containing a first compound and a second compound different from the first compound, the first compound having a perovskite structure represented by a compositional formula ABX3 where A represents a monovalent cation, B represents a divalent cation, and X represents a halogen anion, the second compound containing the divalent cation; and a second electrode on the light-absorbing layer. The light-absorbing layer satisfies 0.05≦[A]/[B]≦0.99, where [A] is a number of moles of the monovalent cation in the light-absorbing layer, and [B] is a number of moles of the divalent cation in the light-absorbing layer.

### BACKGROUND

1. Technical Field

The present disclosure relates to solar cells and particularly relates to a perovskite solar cell.

2. Description of the Related Art

In recent years, solar cells containing a perovskite-type crystal and similar structure serving as a light-absorbing material have been under development. The perovskite-type crystal is represented by the formula ABX₃, where A is a monovalent cation, B is a divalent cation, and C is a halogen anion.

Julian Burschuka et al., “Nature” (the United States of America), No. 499 (July, 2013), pp. 316-320 discloses a solar cell which includes a CH₃NH₃PbI₃ perovskite layer serving as a light-absorbing layer and which contains titanium oxide serving as an electron transport material and 2,2′,7,7′-tetrakis(N,N-di-p-methoxyphenylamine)-9,9′-spirobifluorene (spiro-OMeTAD) serving as a hole transport material.

### SUMMARY

Solar cells containing a perovskite light-absorbing material are required to have increased conversion efficiency.

In one general aspect, the techniques disclosed here feature a solar cell including a first electrode; a light-absorbing layer, on the first electrode, containing a first compound and a second compound different from the first compound, the first compound having a perovskite structure represented by a compositional formula ABX3 where A represents a monovalent cation, B represents a divalent cation, and X represents a halogen anion, the second compound containing the divalent cation; and a second electrode on the light-absorbing layer. The light-absorbing layer satisfies 0.05≦[A]/[B]≦0.99, where [A] is a number of moles of the monovalent cation in the light-absorbing layer, and [B] is a number of moles of the divalent cation in the light-absorbing layer.

It should be noted that general or specific embodiments may be implemented as an element, a device, a system, an integrated circuit, or a method. Furthermore, it should be noted that general or specific embodiments may be implemented as an arbitrary combination of an element, a device, a system, an integrated circuit, and a method.

Additional benefits and/or advantages of the disclosed embodiments will become apparent from the specification and drawings. The benefits and/or advantages may be individually obtained by the various embodiments and features specified in the specification and drawings, which need not all be provided in order to obtain one or more of such benefits and/or advantages.

### BRIEF DESCRIPTION OF THE DRAWINGS

FIG. 1 is a sectional view of a solar cell according to a first embodiment;

FIG. 2 is a sectional view of a solar cell according to a second embodiment;

FIG. 3 is a sectional view of a solar cell according to a third embodiment;

FIG. 4 is a sectional view of a solar cell according to a fourth embodiment;

FIG. 5 is a graph showing the relationship between the [A]/[B] ratio of a light-absorbing layer and the deposition rate ratio; and

FIG. 6 is a graph showing the relationship between the relative conversion efficiency of a solar cell and the [A]/[B] ratio of a light-absorbing layer.

### DETAILED DESCRIPTION

Before embodiments of the present disclosure are described, findings obtained by the inventor are described. In a conventional solar cell, an organic halide AX used to form a perovskite layer remains in a light-absorbing layer that is the perovskite layer. Since the organic halide AX is an insulator, the organic halide AX remaining in the perovskite layer breaks the linkage between tracks in which carriers in the perovskite layer move. This reduces the current flowing through the perovskite layer, leading to a reduction in conversion efficiency. The organic halide AX has a low boiling point. Therefore, the remaining organic halide AX is evaporated by heat, whereby the perovskite layer is deteriorated. This is a factor that reduces the heat durability of the solar cell.

In order to cope with the above problems, a configuration according to an embodiment of the present disclosure can reduce the possibility that a surplus of the organic halide AX is present in a light-absorbing layer containing a perovskite compound. This enables a solar cell having high conversion efficiency and high durability to be provided.

Embodiments of the present disclosure are described below with reference to the accompanying drawings.

### First Embodiment

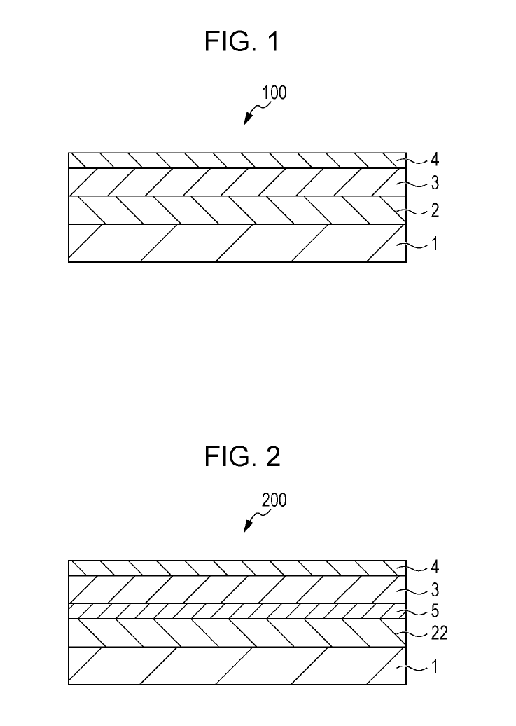

As shown in FIG. 1, a solar cell 100 according to this embodiment includes a substrate 1 and also includes a first collector 2, light-absorbing layer 3, and second collector 4 stacked on the substrate 1 in this order.

The light-absorbing layer 3 contains a perovskite compound represented by the formula ABX₃ and a compound which contains the B and which is different from the perovskite compound, where A is a monovalent cation, B is a divalent cation, and X is an anion. The molar ratio of the cation A to the cation B satisfies the following inequality:

0.05≦[A]/[B]≦0.99 (1)

where [A] is the number of moles of the cation A in the light-absorbing layer 3 and [B] is the number of moles of the cation B in the light-absorbing layer 3.

The solar cell 100 may lack the substrate 1.

The basic action of the solar cell 100 is described below.

When the solar cell 100 is irradiated with light, the light-absorbing layer 3 absorbs light to generate excited electrons and holes. The excited electrons move to the first collector 2. The holes move to the second collector 4. This allows the solar cell 100 to draw a current through the first collector 2 and the second collector 4. The first collector 2 serves as a negative electrode and the second collector 4 serves as a positive electrode.

The molar ratio of the cation A to the cation B in the light-absorbing layer 3 satisfies Inequality (1). This allows the solar cell 100 to improve conversion efficiency and durability. The reason for this is as described below.

The perovskite compound in the light-absorbing layer 3 is synthesized from, for example, an organic halide AX and an inorganic halide BX₂. Since the molar ratio of the cation A to the cation B in the light-absorbing layer 3 satisfies Inequality (1), the number of moles of the cation A in the light-absorbing layer 3 is 1% or more less than the number of moles of the cation B in the light-absorbing layer 3.

This means that almost all the cation A in the organic halide AX is consumed in forming the perovskite compound and therefore the possibility that the organic halide AX is not present in the light-absorbing layer 3 is high. Thus, the fact that the molar ratio of the cation A to the cation B in the light-absorbing layer 3 satisfies Inequality (1) allows the possibility that only the perovskite compound and the compound containing the cation B are present in the light-absorbing layer 3 to be raised. This allows the breakage of the linkage between tracks in which carriers in the perovskite compound move, which is caused by the presence of the organic halide AX, to be reduced. Thus, in the solar cell 100, the reduction of a current is suppressed. Furthermore, the possibility that the organic halide AX, which has a low boiling point, is contained in the light-absorbing layer 3 is low and therefore the light-absorbing layer 3 is unlikely to be deteriorated by heat. These allow the solar cell 100 to improve conversion efficiency and durability.

In this embodiment, the solar cell 100 can be produced by, for example, a method below. First, the first collector 2 is formed on a surface of the substrate 1 by a sputtering process or the like. Next, the light-absorbing layer 3 is formed on the first collector 2 by a vacuum evaporation process or the like. Next, the second collector 4 is formed on the light-absorbing layer 3 by a vacuum evaporation process or the like, whereby the solar cell 100 can be obtained.

Components of the solar cell 100 are described below in detail.

### Substrate 1

The substrate 1 is an auxiliary component. The substrate 1 supports layers in the solar cell 100. The substrate 1 can be formed from a transparent material. The substrate 1 used may be, for example, a glass substance or a plastic substrate (including a plastic film). When the first collector 2 has sufficient strength, the first collector 2 can support the layers and therefore the substrate 1 need not necessarily be used.

### First Collector 2

The first collector 2 is conductive. The first collector 2 does not form any ohmic contact with the light-absorbing layer 3. The first collector 2 has the property of blocking holes coming from the light-absorbing layer 3. The property of blocking the holes coming from the light-absorbing layer 3 is a property that does not allow the holes to pass but allows electrons generated in the light-absorbing layer 3 to pass. A material having such a property is one having a Fermi level higher than the lower energy level of the valence band of the light-absorbing layer 3 and is particularly aluminium.

The first collector 2 is light-transmissive. The first collector 2 transmits light in, for example, the visible to near-infrared range. The first collector 2 can be formed using, for example, a transparent conductive metal oxide. Examples of the transparent conductive metal oxide include indium tin oxide; antimony-doped tin oxide; fluorine-doped tin oxide; zinc oxide doped with at least one selected from the group consisting of boron, aluminium, gallium, and indium; and composites of these compounds. The first collector 2 may have a pattern with an opening through which light passes. Examples of the pattern include linear (striped) patterns, wavy patterns, grid (mesh) patterns, punching metal (arrays of many fine through-holes regularly or irregularly arranged) patterns, and patterns inverted from these patterns. When the first collector 2 has the pattern, light can pass through the opening. Therefore, an opaque material can be used to form the first collector 2.

The first collector 2 desirably has a transmittance of, for example, 50% or more and more desirably 80% or more. The wavelength of light that the first collector 2 should transmit depends on the absorption wavelength of the light-absorbing layer 3. The first collector 2 has a thickness of, for example, 1 nm to 1,000 nm.

### Light-Absorbing Layer 3

The light-absorbing layer 3 contains the perovskite compound, which is represented by the formula ABX₃. The cation A is a monovalent cation. Examples of the cation A include alkali metal cations and monovalent organic cations. Specific examples of the cation A include a methylammonium cation (CH₃NH₃⁺), a formamidinium cation (NH₂CHNH₂⁺), and a cesium cation (Cs⁺). The cation B is a divalent cation. Examples of the cation B include divalent cations of transition metals and group 13 to 15 elements. Specific examples of the cation B include Pb²⁺, Ge²⁺, and Sn²⁺. The anion X is a monovalent anion such as a halogen anion. The site of each of the cation A, the cation B, and the anion X may be occupied by different types of ions. Examples of the perovskite compound include CH₃NH₃PbI₃, CH₃CH₂NH₃PbI₃, NH₂CHNH₂PbI₃, CH₃NH₃PbBr₃, CH₃NH₃PbCl₃, CsPbI₃, and CsPbBr₃.

The thickness of the light-absorbing layer 3 depends on the degree of light absorption and is, for example, 100 nm or more and 1,000 nm or less. The light-absorbing layer 3 can be formed by a co-deposition process or the like.

### Second Collector 4

The second collector 4 is conductive. The second collector 4 does not form any ohmic contact with the light-absorbing layer 3. The second collector 4 has the property of blocking electrons coming from the light-absorbing layer 3. The property of blocking the electrons coming from the light-absorbing layer 3 is a property that does not allow the electrons to pass but allows holes generated in the light-absorbing layer 3 to pass. A material having such a property is one having a Fermi level higher than the upper energy level of the valence band of the light-absorbing layer 3 and is particularly gold or a carbon material such as graphene.

### Second Embodiment

A solar cell 200 according to this embodiment is different from the solar cell 100 according to the first embodiment in that an electron transport layer is added.

The solar cell 200 is described below. Components having the same function and configuration as those used to describe the solar cell 100 according to the first embodiment are given the same reference numerals and will not be described in detail.

As shown in FIG. 2, the solar cell 200 includes a substrate 1 and also includes a first collector 22, electron transport layer 5, light-absorbing layer 3, and second collector 4 stacked on the substrate 1 in that order. The electron transport layer 5 is placed between the first collector 22 and the light-absorbing layer 3. A surface of the electron transport layer 5 that faces the light-absorbing layer 3 is desirably flat. The light-absorbing layer 3 is desirably placed directly on the electron transport layer 5.

The solar cell 200 may lack the substrate 1.

The basic action of the solar cell 200 is described below.

When the solar cell 200 is irradiated with light, the light-absorbing layer 3 absorbs light to generate excited electrons and holes. The excited electrons move through the electron transport layer 5 to the first collector 22. The holes generated in the light-absorbing layer 3 move to the second collector 4. This allows the solar cell 200 to draw a current through the first collector 22 and the second collector 4. The first collector 22 serves as a negative electrode and the second collector 4 serves as a positive electrode.

In this embodiment, substantially the same effect as that described in the first embodiment is obtained.

In this embodiment, the electron transport layer 5 is used. Therefore, the first collector 22 need not have the property of blocking holes coming from the light-absorbing layer 3. This broadens the range of material options for the first collector 22.

In this embodiment, the surface of the electron transport layer 5 that faces the light-absorbing layer 3 is desirably flat. The term “flat” as used herein means that the surface of the electron transport layer 5 that faces the light-absorbing layer 3 has an arithmetic mean roughness Ra of less than 50 nm. The light-absorbing layer 3 is placed directly on the electron transport layer 5. This configuration allows the electron transport layer 5, which is necessary to cover a surface of the first collector 22, to have a small thickness. That is, the resistance of the electron transport layer 5 can be reduced. This allows the loss of the current, generated in the light-absorbing layer 3, in the solar cell 200 to be reduced. Thus, the conversion efficiency of the solar cell 200 can be increased.

The arithmetic mean roughness of a surface of the electron transport layer 5 can be determined from a cross-sectional image observed by, for example, scanning electron microscopy or atomic force microscopy.

In this embodiment, the solar cell 200 can be produced by substantially the same method as that used to produce the solar cell 100 according to the first embodiment. The electron transport layer 5 is formed on the first collector 22 by a sputtering process or the like.

Components of the solar cell 200 are described below in detail.

### First Collector 22

The first collector 22 is conductive. The first collector 22 may have substantially the same configuration as that of the first collector 2 described in the first embodiment. In this embodiment, the electron transport layer 5 is used and therefore the first collector 22 need not have the property of blocking the hole coming from the light-absorbing layer 3. That is, the first collector 22 may be made of a material forming an ohmic contact with the light-absorbing layer 3.

The first collector 22 is light-transmissive. The first collector 22 transmits light in, for example, the visible to near-infrared range. The first collector 22 can be formed using a transparent conductive metal oxide. Examples of the transparent conductive metal oxide include indium tin oxide; antimony-doped tin oxide; fluorine-doped tin oxide; zinc oxide doped with at least one selected from the group consisting of boron, aluminium, gallium, and indium; and composites of these compounds.

The first collector 22 may be made of an opaque material. In this case, as is the case with the first collector 2 described in the first embodiment, the first collector 22 is formed so as to have a pattern allowing light to pass through. Examples of the opaque material include platinum, gold, silver, copper, aluminium, rhodium, indium, titanium, iron, nickel, tin, zinc, and alloys containing any one of these metals. A conductive carbon material can be used to form the first collector 22.

The first collector 22 desirably has a light transmittance of, for example, 50% or more and more desirably 80% or more. The wavelength of light that the first collector 22 should transmit depends on the absorption wavelength of the light-absorbing layer 3. The first collector 22 has a thickness of, for example, 1 nm or more and 1,000 nm or less.

### Electron Transport Layer 5

The electron transport layer 5 contains a semiconductor. In particular, the semiconductor desirably has a band gap of 3.0 eV or more. Forming the electron transport layer 5 using the semiconductor, which has a band gap of 3.0 eV or more, enables visible light and infrared light to reach the light-absorbing layer 3. Examples of the semiconductor include n-type organic semiconductors and n-type inorganic semiconductors.

Examples of the n-type organic semiconductors include imide compounds, quinone compounds, fullerenes, and derivatives of these compounds. Examples of the n-type inorganic semiconductors include metal oxides and perovskite oxides. Examples of the metal oxides include oxides of Cd, Zn, In, Pb, Mo, W, Sb, Bi, Cu, Hg, Ti, Ag, Mn, Fe, V, Sn, Zr, Sr, Ga, and Cr. Specific examples of the n-type inorganic semiconductors include TiO₂. Examples of the perovskite oxides include SrTiO₃ and CaTiO₃.

The electron transport layer 5 may be made of a material with a band gap of more than 6 eV. Examples of the material with a band gap of more than 6 eV include alkali metal halides such as lithium fluoride, alkaline-earth metal halides such as calcium fluoride, alkali metal oxides such as magnesium oxide, and silicon dioxide. In order to ensure the electron transportability of the electron transport layer 5, the thickness of the electron transport layer 5 is, for example, 10 nm or less.

The electron transport layer 5 may include a plurality of sub-layers made of different materials. A boundary portion of the electron transport layer 5 may be mixed with a boundary portion of the light-absorbing layer 3.

### Third Embodiment

A solar cell 300 according to this embodiment is different from the solar cell 100 according to the first embodiment in that an hole transport layer is added.

The solar cell 300 is described below. Components having the same function and configuration as those used to describe the solar cell 100 according to the first embodiment are given the same reference numerals and will not be described in detail.

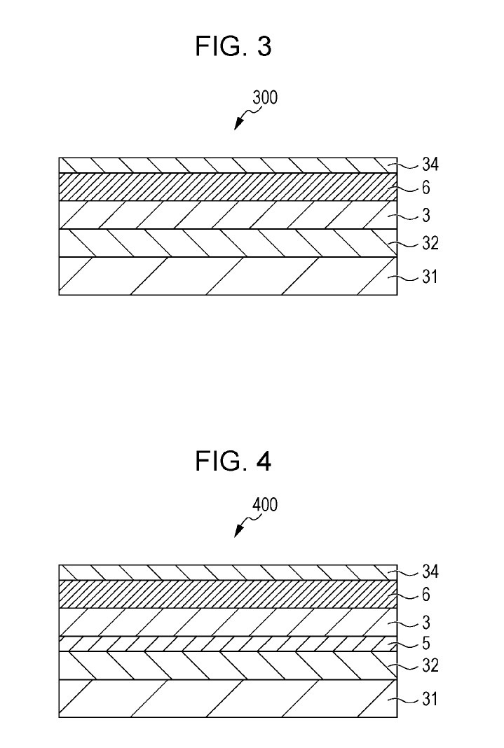

As shown in FIG. 3, the solar cell 300 includes a substrate 31 and also includes a first collector 32, light-absorbing layer 3, hole transport layer 6, and second collector 34 stacked on the substrate 31 in that order. The hole transport layer 6 is placed between the light-absorbing layer 3 and the second collector 34.

The solar cell 300 may lack the substrate 31.

The basic action of the solar cell 300 is described below.

When the solar cell 300 is irradiated with light, the light-absorbing layer 3 absorbs light to generate excited electrons and holes. The excited electrons move to the first collector 32. The holes generated in the light-absorbing layer 3 move through the hole transport layer 6 to the second collector 34. This allows the solar cell 300 to draw a current through the first collector 32 and the second collector 34. The first collector 32 serves as a negative electrode and the second collector 34 serves as a positive electrode.

In this embodiment, substantially the same effect as that described in the first embodiment is obtained.

In this embodiment, the hole transport layer 6 is used. Therefore, the second collector 34 need not have the property of blocking electrons coming from the light-absorbing layer 3. This broadens the range of material options for the second collector 34.

In this embodiment, the solar cell 300 can be produced by substantially the same method as that used to produce the solar cell 100 according to the first embodiment. The hole transport layer 6 is formed on the light-absorbing layer 3 by a coating process or the like.

Components of the solar cell 300 are described below in detail.

### Substrate 31

The substrate 31 is an auxiliary component and may have substantially the same configuration as that of the substrate 1 described in the first embodiment. When the second collector 34 is light-transmissive, the substrate 31 can be formed using an opaque material. For example, a metal material, a ceramic material, and a resin material with low light transmittance can be used to form the substrate 31.

### Hole Transport Layer 6

The hole transport layer 6 is made of, for example, an organic material or an inorganic semiconductor. The hole transport layer 6 may include a plurality of sub-layers made of different materials. The hole transport layer 6 may be partly mixed with the light-absorbing layer 3.

Examples of the organic material include phenylamine and triphenylamine derivatives, which each contain a tertiary amine in their skeletons, and polyethylenedioxythiophene (PEDOT) derivatives with a thiophene structure. The molecular weight of the organic material is not particularly limited. The organic material may be a polymer. In the case where the hole transport layer 6 is formed using the organic material, the hole transport layer 6 desirably has a thickness of 1 nm or more and 1,000 nm or less, and more desirably 100 nm or more and 500 nm or less. When the thickness of the hole transport layer 6 is within this range, sufficient hole transportability can be exhibited and low resistance can be maintained; hence, photovoltaic can be carried out with high efficiency.

The inorganic semiconductor used may be, for example, a p-type semiconductor. Examples of the p-type semiconductor include CuO, Cu₂O, CuSCN, molybdenum oxide, and nickel oxide. In the case where the hole transport layer 6 is formed using the inorganic semiconductor, the hole transport layer 6 desirably has a thickness of 1 nm or more and 1,000 nm or less, and more desirably 10 nm or more and 50 nm or less. When the thickness of the hole transport layer 6 is within this range, sufficient hole transportability can be exhibited and low resistance can be maintained; hence, photovoltaic can be carried out with high efficiency.

The hole transport layer 6 can be formed by a coating process or a printing process. Examples of the coating process include a doctor blade process, a bar-coating process, a spraying process, a dip-coating process, and a spin-coating process. An example of the printing process is a screen-printing process. The hole transport layer 6 may be formed by pressing or firing a film of a mixture as required. When a material used to form the hole transport layer 6 is a low-molecular-weight organic substance or the inorganic semiconductor, the hole transport layer 6 can be formed by a vacuum evaporation process.

The hole transport layer 6 may contain a supporting electrolyte and a solvent.

Examples of the supporting electrolyte include ammonium salts and alkali metal salts. Examples of the ammonium salts include tetrabutylammonium perchlorate, tetraethylammonium hexafluorophosphate, imidazolium salts, and pyridinium salts. Examples of the alkali metal salts include lithium perchlorate and potassium tetrafluoroborate.

The solvent, which is contained in the hole transport layer 6, desirably has excellent ion conductivity. The solvent used may be either of an aqueous solvent and an organic solvent. In order to stabilize a solute, the organic solvent is desirable. Examples of the organic solvent include carbonate compounds, ester compounds, ether compounds, heterocyclic compounds, nitrile compounds, and aprotic polar compounds.

Examples of the carbonate compounds include dimethyl carbonate, diethyl carbonate, methyl ethyl carbonate, ethylene carbonate, and propylene carbonate. Examples of the ester compounds include methyl acetate, methyl propionate, and γ-butyrolactone. Examples of the ether compounds include diethyl ether, 1,2-dimethoxyethane, 1,3-dioxolane, tetrahydrofuran, and 2-methyl-tetrahydrofuran. Examples of the heterocyclic compounds include 3-methyl-2-oxazolidinone and N-methylpyrrolidone. Examples of the nitrile compounds include acetonitrile, methoxyacetonitrile, and propionitrile. Examples of the aprotic polar compounds include sulfolane, dimethyl sulfoxide, and dimethylformamide.

These compounds may be used alone or in combination. In particular, the following compounds are desirable: the carbonate compounds, such as ethylene carbonate and propylene carbonate; the heterocyclic compounds, such as γ-butyrolactone, 3-methyl-2-oxazolidinone and N-methylpyrrolidone; and the nitrile compounds, such as acetonitrile, methoxyacetonitrile, propionitrile, 3-methoxypropionitrile, and valeronitrile.

The solvent used may be a single ionic liquid or a mixture of the ionic liquid and another solvent. The ionic liquid has low volatility, is highly flame-retardant, and therefore is desirable.

The ionic liquid used may be, for example, an imidazolinium-based ionic liquid such as 1-ethyl-3-methylimidazolinium tetracyanoborate, a pyridine-based ionic liquid, an alicyclic amine-based ionic liquid, an aliphatic amine-based ionic liquid, or an azonium amine-based ionic liquid.

### First Collector 32 and Second Collector 34

In this embodiment, the hole transport layer 6 is used and therefore the second collector 34 need not have the property of blocking the hole coming from the light-absorbing layer 3. That is, the second collector 34 may be made of a material forming an ohmic contact with the light-absorbing layer 3. Therefore, the second collector 34 may be formed so as to be light-transmissive.

At least one of the first collector 32 and the second collector 34 is light-transmissive. At least one of the first collector 32 and the second collector 34 that is light-transmissive may have the same configuration as that of the first collector 22 described in the second embodiment.

One of the first collector 32 and the second collector 34 may be opaque. One of the first collector 32 and the second collector 34 that is opaque can be formed using an opaque material selected from the materials that can be used to form the first collector 22 described in the second embodiment. A region where no electrode material is present need not be formed in one of the first collector 32 and the second collector 34 that is opaque.

### Fourth Embodiment

A solar cell 400 according to this embodiment is different from the solar cell 200 according to the second embodiment in that a hole transport layer is added. In other words, the solar cell 400 is configured by adding an electron transport layer to the solar cell 300 according to the third embodiment.

The solar cell 400 is described below. Components having the same function and configuration as those used to describe the solar cell 200 according to the first embodiment and the solar cell 300 according to the third embodiment are given the same reference numerals and will not be described in detail.

As shown in FIG. 4, the solar cell 400 includes a substrate 31 and also includes a first collector 32, electron transport layer 5, light-absorbing layer 3, hole transport layer 6, and second collector 34 stacked on the substrate 1 in that order.

The solar cell 400 may lack the substrate 31.

The basic action of the solar cell 400 is described below.

When the solar cell 400 is irradiated with light, the light-absorbing layer 3 absorbs light to generate excited electrons and holes. The excited electrons move through the electron transport layer 5 to the first collector 32. The holes generated in the light-absorbing layer 3 move through the hole transport layer 6 to the second collector 34. This allows the solar cell 400 to draw a current through the first collector 32 and the second collector 34. The first collector 32 serves as a negative electrode and the second collector 34 serves as a positive electrode.

In this embodiment, substantially the same effects as those described in the second and third embodiments are obtained.

In this embodiment, the solar cell 400 can be produced by substantially the same method as that used to produce the solar cell 200 according to the second embodiment and the solar cell 300 according to the third embodiment.

In each of the above embodiments, an electron injection layer may be placed between the first collector 2, 22, or 32 and the light-absorbing layer 3. The presence of the electron injection layer enables the movement of electrons from the light-absorbing layer 3 to the first electrode 2, 22, or 32 to be promoted. Examples of a material used to form the electron injection layer include alkali metals, alkaline-earth metals such as barium and calcium, halides of these metals, and chalcogenides of these metals. For example, oxides such as zinc oxide and titanium oxide can be used to form the electron injection layer.

A hole injection layer may be placed between the second collector 4 or 34 and the light-absorbing layer 3. The presence of the hole injection layer enables the migration of holes from the light-absorbing layer 3 to the second collector 4 or 34 to be promoted. For example, a thiophene compound and an oxide semiconductor can be used to form the hole injection layer. An example of the thiophene compound is polyethylenedioxythiophene polystyrene sulfonate (PEDOT-PSS). Examples of the oxide semiconductor include MoO₃, WO₃, and NiO.

A sealing layer may be placed on the second collector 34. The sealing layer seals the whole of the solar cell 400. The presence of the sealing layer allows the exposure of the solar cell 400 to air to be suppressed. This enables moisture and oxygen in air to be prevented from penetrating the solar cell 400; hence, the durability of the solar cell 400 can be increased. Examples of a material used to form the sealing layer include silicon nitride (SiN), silicon oxynitride (SiON), and resin.

A box-shaped sealing glass may be placed around the solar cell 400. The presence of the sealing glass allows the solar cell 400 to be spatially isolated from the outside. This enables an effect similar to the sealing layer to be obtained. The sealing glass can be formed using, for example, substantially the same material as that used to form the substrate 1. A material absorbing moisture, oxygen, or the like is desirably provided in the sealing glass.

In each of the above embodiments, a configuration in which the electron transport layer is placed on the substrate side is described. However, the present disclosure is not limited to this configuration. The hole transport layer may be placed on the substrate side.

### EXAMPLES

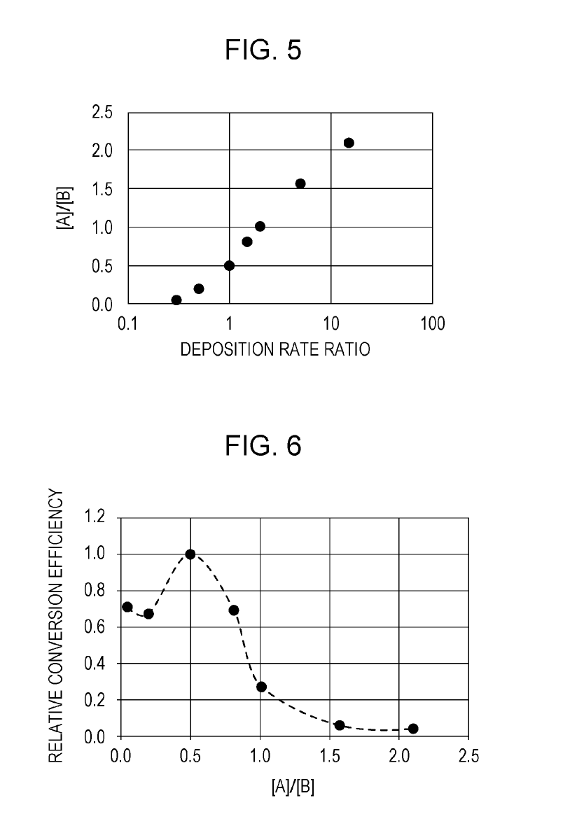

The present disclosure is further described below in detail with reference to examples. Solar cells were produced in Examples 1 to 4 and Comparative Examples 1 to 3 and were evaluated for characteristics. Evaluation results are shown in the Table and FIGS. 5 and 6.

### Example 1

A solar cell having the same structure as that of the solar cell 400 shown in FIG. 4 was produced.

The solar cell of Example 1 was produced as described below.

A glass substrate was set in a chamber of a sputtering system. A predetermined sputtering gas was introduced into the chamber, followed by depositing a first collector made of fluorine-doped tin oxide (FTO) on the glass substrate by a reactive sputtering process. The first collector had a thickness of about 300 nm.

Next, an electron transport layer made of titanium oxide was provided on the first collector by a reactive sputtering process. The electron transport layer had a thickness of about 30 nm.

Next, the glass substrate provided with the first collector and the electron transport layer was set in a chamber of a vacuum evaporation system. Furthermore, a crucible filled with lead iodide and a crucible filled with methylammonium iodide were set in the vacuum evaporation system. Co-deposition was performed in such a manner that the crucibles were heated and the ratio (hereinafter referred to as the deposition rate ratio) of the deposition rate of methylammonium iodide to the deposition rate of lead iodide was set to 0.3. Next, the glass substrate was placed on a hotplate set to 130° C. and was heated for 45 minutes in an inert gas atmosphere, whereby a light-absorbing layer containing the perovskite compound CH₃NH₃PbI₃ was provided on the electron transport layer. The light-absorbing layer had a thickness of about 300 nm.

Next, a hole transport layer containing spiro-OMeTAD was provided on the light-absorbing layer by a spin coating process. The hole transport layer had a thickness of about 100 nm. Thereafter, a second collector made of gold was provided on the hole transport layer by a resistive heating evaporation process. The second collector had a thickness of about 100 nm.

### Examples 2 to 4 and Comparative Examples 1 to 3

In each of Examples 2 to 4 and Comparative Examples 1 to 3, a solar cell was produced in substantially the same manner as that used to produce the solar cell of Example 1 except that in Example 2, the deposition rate ratio for the formation of a light-absorbing layer was set to 0.5; in Example 3, the deposition rate ratio for the formation of a light-absorbing layer was set to 1.0; in Example 4, the deposition rate ratio for the formation of a light-absorbing layer was set to 1.5; in Comparative Example 1, the deposition rate ratio for the formation of a light-absorbing layer was set to 2.0; in Comparative Example 2, the deposition rate ratio for the formation of a light-absorbing layer was set to 5.0; and in Comparative Example 3, the deposition rate ratio for the formation of a light-absorbing layer was set to 15.0.

### Evaluation Method

### Measurement of Molar Ratio

The composition of each light-absorbing layer was measured with an electron probe microanalyzer (EPMA). In general, depth resolution in EPMA measurement is on the order of micrometer from a surface of a measurement object. Thus, information on the average composition of the light-absorbing layer, which has a thickness of about 300 nm, can be obtained as a measurement result.

In each of Examples 1 to 4 and Comparative Examples 1 to 3, the perovskite compound, represented by the formula ABX₃, in the light-absorbing layer was CH₃NH₃PbI₃. That is, a cation A was CH₃NH₃⁺ and a cation B was Pb2⁺. The number of moles [A] of the cation A in the light-absorbing layer and the number of moles [B] of the cation B in the light-absorbing layer could be determined by analyzing the amount of nitrogen and the amount of lead, respectively, in the light-absorbing layer. Therefore, the molar ratio [A]/[B] was calculated from analysis results.

### Measurement of Conversion Efficiency

Each solar cell was connected in series to a direct-current power supply and was supplied with a voltage while being irradiated with light at an intensity of 1 sun. The voltage applied to the solar cell was varied and the current flowing through the solar cell was converted into a value (current density) per unit area of the solar cell. A value obtained by dividing the maximum of the generated electrical power given by the product of the applied voltage and the current density by a light energy of 1 sun was calculated as conversion efficiency.

TABLE

| | Deposition | Molar ratio | Relative conversion |
|---|---|---|---|
| | rate ratio | [A]/[B] | efficiency |
| Example 1 | 0.3 | 0.05 | 0.71 |
| Example 2 | 0.5 | 0.20 | 0.67 |
| Example 3 | 1.0 | 0.50 | 1 |
| Example 4 | 1.5 | 0.81 | 0.69 |
| Comparative | 2.0 | 1.01 | 0.27 |
| Example 1 | | | |
| Comparative | 5.0 | 1.57 | 0.06 |
| Example 2 | | | |
| Comparative | 15.0 | 2.10 | 0.04 |
| Example 3 | | | |

FIG. 5 shows the [A]/[B] ratio of the light-absorbing layer in the solar cell of each of Examples 1 to 4 and Comparative Examples 1 to 3. In FIG. 5, the horizontal axis represents the deposition rate ratio used to produce the solar cell on a logarithmic scale. As is clear from FIG. 5, increasing the deposition rate ratio increases the [A]/[B] ratio of the light-absorbing layer. Furthermore, the [A]/[B] ratio of the light-absorbing layer increases substantially linearly with the deposition rate ratio, which is shown on the logarithmic scale.

FIG. 6 is a graph in which the horizontal axis represents the [A]/[B] ratio of the light-absorbing layer in the solar cell of each of Examples 1 to 4 and Comparative Examples 1 to 3 and the vertical axis represents the relative conversion efficiency. The relative conversion efficiency is a value obtained by dividing the conversion efficiency of each solar cell by the conversion efficiency of the solar cell of Example 3, the conversion efficiency of the solar cell of Example 3 being maximal. In FIG. 6, a dotted line is a fitted curve that represents the relationship between the [A]/[B] ratio and the relative conversion efficiency.

As is clear from results shown in the Table, the solar cell of Example 3, in which the [A]/[B] ratio of the light-absorbing layer is 0.5, has the maximum conversion efficiency. The solar cells of Examples 1, 2, and 4 have a high conversion efficiency of 0.6 or more. However, the solar cells of Comparative Examples 1 to 3 have a low conversion efficiency of less than about 0.3.

As described above, a configuration in which the molar ratio of a cation A to a cation B in a light-absorbing layer satisfies Inequality (1) allows a solar cell to have increased conversion efficiency.

A solar cell according to the present disclosure is useful as a photoelectric converter or a photosensor.

What is claimed is:

1. A solar cell comprising:
a first electrode;
a light-absorbing layer, on the first electrode, containing a first compound and a second compound different from the first compound, the first compound having a perovskite structure represented by a compositional formula ABX₃ where A represents a monovalent cation, B represents a divalent cation, and X represents a halogen anion, the second compound containing the divalent cation; and
a second electrode on the light-absorbing layer, wherein
the light-absorbing layer satisfies
0.05≦[A]/[B]≦0.99 (1)
where [A] is a number of moles of the monovalent cation in the light-absorbing layer, and [B] is a number of moles of the divalent cation in the light-absorbing layer.

2. The solar cell according to claim 1, wherein the monovalent cation comprises at least one selected from the group consisting of a methylammonium cation and a formamidinium cation.

3. The solar cell according to claim 1, wherein the divalent cation comprises at least one selected from the group consisting of Pb²⁺, Ge²⁺, and Sn²⁺.

4. The solar cell according to claim 1, further comprising an electron transport layer between the first electrode and the light-absorbing layer.

5. The solar cell according to claim 1, further comprising a hole transport layer between the light-absorbing layer and the second electrode.

6. The solar cell according to claim 4, wherein
the light-absorbing layer has a surface in direct contact with the electron transport layer, and
the surface has an arithmetic mean roughness of less than 50 nm.
